(19) United States
(12) Patent Application Publication
(10) Pub. No.: US 2012/0118732 A1
(43) Pub. Date: May 17, 2012

(54) FILM FORMATION APPARATUS

(75) Inventors: Shuji Kodaira, Susono-shi (JP); Tomoyuki Yoshihama, Susono-shi (JP); Koukichi Kamada, Susono-shi (JP); Kazumasa Horita, Susono-shi (JP); Junichi Hamaguchi, Susono-shi (JP); Shigeo Nakanishi, Susono-shi (JP); Satoru Toyoda, Susono-shi (JP)

(73) Assignee: ULVAC, INC., Chigasaki-shi (JP)

(21) Appl. No.: 13/383,688

(22) PCT Filed: Jul. 15, 2010
(86) PCT No.: PCT/JP2010/061973

§ 371 Date: Jan. 12, 2012

(30) Foreign Application Priority Data
Jul. 17, 2009 (JP) P2009-169449

(51) Int. Cl. C23C 14/35

(52) U.S. Cl. 204/298.08

(57) ABSTRACT

A film formation apparatus includes: a chamber having a side wall and an inner space in which both a body to be processed and a target are disposed a first magnetic field generation section generating a magnetic field in the inner space a second magnetic field generation section disposed at a position close to the target, the second magnetic field generation section generating a magnetic field so as to allow perpendicular magnetic lines of force thereof to pass through a position adjacent to the target; and a third magnetic field generation section disposed at a position close to the body to be processed, the third magnetic field generation section generating a magnetic field so as to induce the magnetic lines of force to the side wall of the chamber.

### CROSS-REFERENCE TO RELATED APPLICATION

This is the U.S. National Phase Application under 35 U.S.C. §371 of International Patent Application No. PCT/JP2010/061973 filed Jul. 15, 2010, which designated the United States and was published in a language other than English, which claims the benefit of Japanese Patent Application No. 2009-169449 filed on Jul. 17, 2009, both of them are incorporated by reference herein. The International Application was published in Japanese on Jan. 20, 2011 as WO2011/007830 A1 under PCT Article 21(2).

### BACKGROUND OF THE INVENTION

1. Field of the Invention

The present invention relates to a film formation apparatus used for forming a film on a surface of a body to be processed, and particularly, relates to a film formation apparatus by use of a DC magnetron method using a sputtering method which is one of several thin film forming methods.

2. Background Art

Conventionally, a film formation apparatus using a sputtering method (hereinafter, refer to “sputtering apparatus”) is used in a film formation step in which, for example, a semiconductor device is manufactured.

As a sputtering apparatus of such intended use, with miniaturizing of wiring pattern in recent years, an apparatus is increasingly and strongly required in a film can be formed over an entire surface of a substrate to be processed with excellent coatability in microscopic holes or trenches having a high-aspect ratio, and microscopic patterns.

In a commonly-used sputtering apparatus, a target is disposed inside a vacuum chamber into which a sputtering gas is introduced, the sputtering gas (for example, argon gas) is ionized by applying a negative voltage to the target, and the sputtering gas thereby collides with the target.

Due to this colliding, sputtered particles are flied out from the surface of the target.

The target is made of a material such as Cu, Al, Ti, Ta, or the like (material used to form a wiring made of a thin film).

Consequently, atoms of Cu, Al, Ti, or Ta serving as sputtered particles are scattered from the target, the material thereof is adhered to a substrate, and a thin film is thereby formed on the substrate.

In the vacuum chamber, the substrate on which the thin film is formed and the target are arranged separately from each other at a predetermined distance and face each other.

Additionally, in a sputtering apparatus using a DC magnetron method, a magnetic field is generated on the top face of the target by a magnetic field generation section (for example, a permanent magnet or the like) that is provided at the back face of the target.

In a state where the magnetic field are generated in the above-described manner, sputtering gas ions collide with the top face of the target by applying a negative voltage to the target, and atoms and secondary electrons constituting the target material are thereby discharged from the target.

Due to the secondary electrons revolving in the magnetic field generated on the top face of the target, the frequency in ionization collision between the sputtering gas (inert gas such as argon gas or the like) and the secondary electrons increases, the plasma density becomes high, and the thin film is thereby formed on the substrate (for example, refer to Japanese Unexamined Patent Application, First Publication No. 2000-144412).

However, in the aforementioned sputtering apparatus, there is a problem in that electrons, argon ions, or metal ions (Cu, Al, Ti, Ta, or the like), which have broken free from the bound state which is due to the magnetic field generated on the top face of the target by the magnetic field generation section, reach the substrate, and the substrate is thereby damaged.

Furthermore, as a result of the electrons colliding with the substrate, the temperature of the substrate surface increases, and there is thereby a problem in that the quality of the substrate becomes degraded.

### SUMMARY OF THE INVENTION

The invention was made in order to solve the above problems, and has an object to provide a film formation apparatus that can prevent damage to a substrate and prevent an increase in temperature of the substrate by controlling the incident directions of argon ions, metal ions, and electrons.

A film formation apparatus of an aspect of the invention includes: a chamber having a side wall and an inner space in which both a body to be processed on which a film is to be formed and a target (base material of a coat) having a sputtering face are disposed (stored) so that the body to be processed is opposed to the target; a pumping section reducing a pressure inside the chamber; a first magnetic field generation section generating a magnetic field in the inner space to which the sputtering face is exposed (anterior to the sputtering face); a direct-current power source applying a negative direct electric current voltage to the target; a gas introduction section introducing a sputter gas into the chamber; a second magnetic field generation section disposed at a position close to the target (near the target), the second magnetic field generation section generating a magnetic field so as to allow perpendicular magnetic lines of force thereof to pass through a position adjacent to the target (near the target); and a third magnetic field generation section disposed at a position close to the body to be processed (near the body to be processed), the third magnetic field generation section generating a magnetic field so as to induce the magnetic lines of force to the side wall of the chamber.

In the film formation apparatus of the aspect of the invention, it is preferable that the second magnetic field generation section and the third magnetic field generation section be distantly-disposed from each other at a predetermined distance around the chamber and be constituted of coils which are provided with a power supply device, and electrical currents be applied to the second magnetic field generation section and the third magnetic field generation section so that a polarity of the electrical current applied to the second magnetic field generation section is opposite to a polarity of the electrical current applied to the third magnetic field generation section.

In the film formation apparatus of the aspect of the invention, it is preferable that magnetic field lines which are generated by the second magnetic field generation section and the third magnetic field generation section be induced to the chamber.

### EFFECTS OF THE INVENTION

In the invention, the second magnetic field generation section disposed at the position close to the target and the third magnetic field generation section disposed at the position close to the body to be processed are used.

Additionally, the second magnetic field generation section generates a magnetic field so that the perpendicular magnetic field lines pass through the position adjacent to the target.

The third magnetic field generation section generates a magnetic field so as to induce the magnetic field lines thereof to the side walls of the chamber.

Consequently, it is possible to control the incident directions of metal ions, argon ions, and electrons and it is possible to prevent damage to a substrate and prevent an increase in temperature of the substrate since the number of metal ions, argon ions, and electrons, which reach the substrate, decreases.

According to the invention, the second magnetic field generation section and the third magnetic field generation section are coils which are provided with a power supply device.

Furthermore, the electrical currents are applied to the second magnetic field generation section and the third magnetic field generation section so that the polarity of the electrical current applied to the second magnetic field generation section is opposite to the polarity of the electrical current applied to the third magnetic field generation section.

Consequently, it is possible to generate a desired magnetic field using a simple constitution.

Moreover, by appropriately changing (controlling) the distance between the coil (the second magnetic field generation section and the third magnetic field generation section), the number of windings of each coil, the electrical current or the like to be supplied to each coil, it is possible to generate a magnetic field such that desired magnetic field lines are formed.

### BRIEF DESCRIPTION OF THE DRAWINGS

FIG. 1 is a cross-sectional view schematically showing the structure of a film formation apparatus related to the invention.

FIG. 2 is a schematic view showing a state where the perpendicular magnetic field is generated in the film formation apparatus related to the invention and showing the case where the electrical current is applied to each of upper and lower coils in the same direction.

FIG. 3 is a schematic view showing a state where the perpendicular magnetic field is generated in the film formation apparatus related to the invention and showing the case where the electrical current is applied to a lower coil in a direction which is opposite to the flow direction of the electrical current of an upper coil.

FIG. 4 is a cross-sectional view schematically showing the structure of a microscopic hole and a trench having a high-aspect ratio, which are formed on a substrate.

FIG. 5 is a diagram illustrating a result of measuring the number of ions and electrons reaching a substrate.

### DESCRIPTION OF THE PREFERRED EMBODIMENTS

Hereinafter, an embodiment of a film formation apparatus related to the invention will be described with reference to drawings.

Additionally, in order to make the respective components be of understandable size in the drawing, the dimensions and the proportions of the respective components are modified as needed compared with the real components in the respective drawings used in the explanation described below.

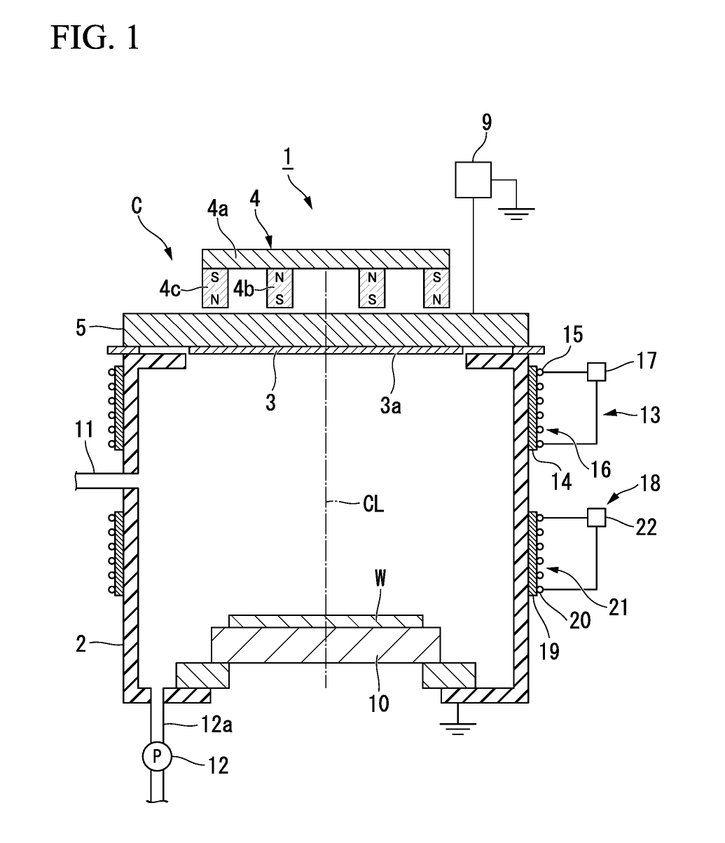

As shown in FIG. 1, a film formation apparatus 1 is a film formation apparatus using a DC magnetron sputtering method and is provided with a vacuum chamber 2 (chamber) capable of generating a vacuum atmosphere.

A cathode unit C is attached to a ceiling portion of the vacuum chamber 2.

Moreover, in the explanation described below, the position close to the ceiling portion of the vacuum chamber 2 is referred to as “upper” and the position close to the bottom portion of the vacuum chamber 2 is referred to as “lower”.

The cathode unit C is provided with a target 3, and the target 3 is attached to a holder 5.

Furthermore, the cathode unit C provided with a first magnetic field generation section 4 generating a tunnel-shaped magnetic field in a space (anterior to sputtering face 3a) to which a sputtering face (lower face) 3a of the target 3 is exposed.

The target 3 is made of a material, for example, Cu, Ti, Al, or Ta, which is appropriately selected in accordance with the composition of the thin film which is to be formed on a substrate W to be processed (body to be processed).

The target 3 is formed in a predetermined shape (e.g., a circular form in a plan view) using a known method so that the shape thereof corresponds to the shape of the substrate W to be processed and so that the surface area of the sputtering face 3a is greater than the surface area of the substrate W.

Additionally, the target 3 is electrically connected to a DC power source 9 (sputtering power source, direct-current power source) having a known structure, and a predetermined negative electrical potential is applied to the target 3.

The first magnetic field generation section 4 is disposed at the position of the holder 5 (upper side, back side of the target 3 or holder 5) opposite to the position at which the target 3 (sputtering face 3a) is disposed.

The first magnetic field generation section 4 is constituted of a yoke 4a disposed in parallel with the target 3 and magnets 4b and 4c provided at a lower face of the yoke 4a.

The magnets 4b and 4c are arranged so that polarities of leading ends of magnets 4b and 4c arranged at the position close to the target 3 are alternately different from each other.

The shape or the number of the magnets 4b and 4c is appropriately determined in accordance with the magnetic field (shape or profile of magnetic field) formed in the space (anterior to the target 3) to which the sputtering face 3a is exposed in terms of improvement of stability of the electric discharge, efficiency in the use of a target, or the like.

As a shape of the magnets 4b and 4c, for example, a lamellate shape, a rod shape, or a shape to which such shapes are appropriately combined may be employed.

Moreover, a transfer mechanism may be provided at the first magnetic field generation section 4, the first magnetic field generation section 4 may be reciprocally moved or rotated at the back face side of the target 3 by the transfer mechanism.

A stage 10 is disposed at the bottom of the vacuum chamber 2 so as to face the target 3.

The substrate W is mounted on the stage 10, the position of the substrate W is determined by the stage 10, and the substrate W is maintained.

Furthermore, one end of a gas pipe 11 (gas introduction section) introducing argon gas serving as a sputter gas thereinto is connected to a side wall of the vacuum chamber 2, and the other end of the gas pipe 11 is communicated with a gas source with a mass-flow controller (not shown in the figure) interposed therebetween.

Additionally, an exhaust pipe 12a which is communicated with a vacuum pumping section 12 (pumping section) is connected to the vacuum chamber 2, and the vacuum pumping section 12 is constituted of a turbo-molecular pump, a rotary pump, or the like.

The second magnetic field generation section 13 and the third magnetic field generation section 18 used for controlling the incident directions of metal ions, argon ions, and electrons, are installed around the vacuum chamber 2 (the outer periphery of the vacuum chamber 2, outer side of the side wall).

The second magnetic field generation section 13 and the third magnetic field generation section 18 are provided at external walls of the vacuum chamber 2 and around the perpendicular axis CL connecting the centers of the target 3 and the substrate W.

The second magnetic field generation section 13 and the third magnetic field generation section 18 are arranged separately from each other at a predetermined distance in the vertical direction of the vacuum chamber 2.

The second magnetic field generation section 13 is provided with a ring-shaped coil support member 14 which is provided at the external walls of the vacuum chamber 2, a second coil 16 which is configured by winding a conductive wire 15 on the coil support member 14, and a power supply device 17 supplying electrical power to the second coil 16.

The third magnetic field generation section 18 is provided with a ring-shaped coil support member 19 which is provided at the external walls of the vacuum chamber 2, a third coil 21 which is configured by winding a conductive wire 20 on the coil support member 19, and a power supply device 22 supplying electrical power to the third coil 21.

The number of the coils, the diameter of the conductive wire 15, or the number of windings of the conductive wire 15 is appropriately determined in accordance with, for example, the lengths of the target 3, the distance between the target 3 and the substrate W, the rated current of the power supply devices 17 and 22, or the intensity (gauss) of the magnetic field to be generated.

The power supply devices 17 and 22 have a known structure including a control circuit (not shown in the figure) that can optionally modulate the current value and the direction of the current to be supplied to each of the second coil 16 and the third coil 21.

In the embodiment, in order to control the incident directions of metal ions, argon ions, and electrons, the current value having negative polarity is applied to the second coil 16 so that a downward perpendicular magnetic field is generated inside the vacuum chamber 2.

In contrast, the current value having positive polarity is applied to the third coil 21 so that an upward perpendicular magnetic field is generated in the vacuum chamber 2.

That is, the polarity of the electrical current in the lower coil 21 is opposite to the polarity of the electrical current in the upper coil 16.

As stated above, due to the electrical currents being applied to the second coil 16 and the third coil 21 so that the polarity of the electrical current applied to the second coil 16 is opposite to the polarity of the electrical current applied to the third coil 21, the directions of the magnetic field lines shown in FIG. 3 are not perpendicular to the substrate W, and the directions are refracted in the vacuum chamber 2 and directed to the side walls of the vacuum chamber 2.

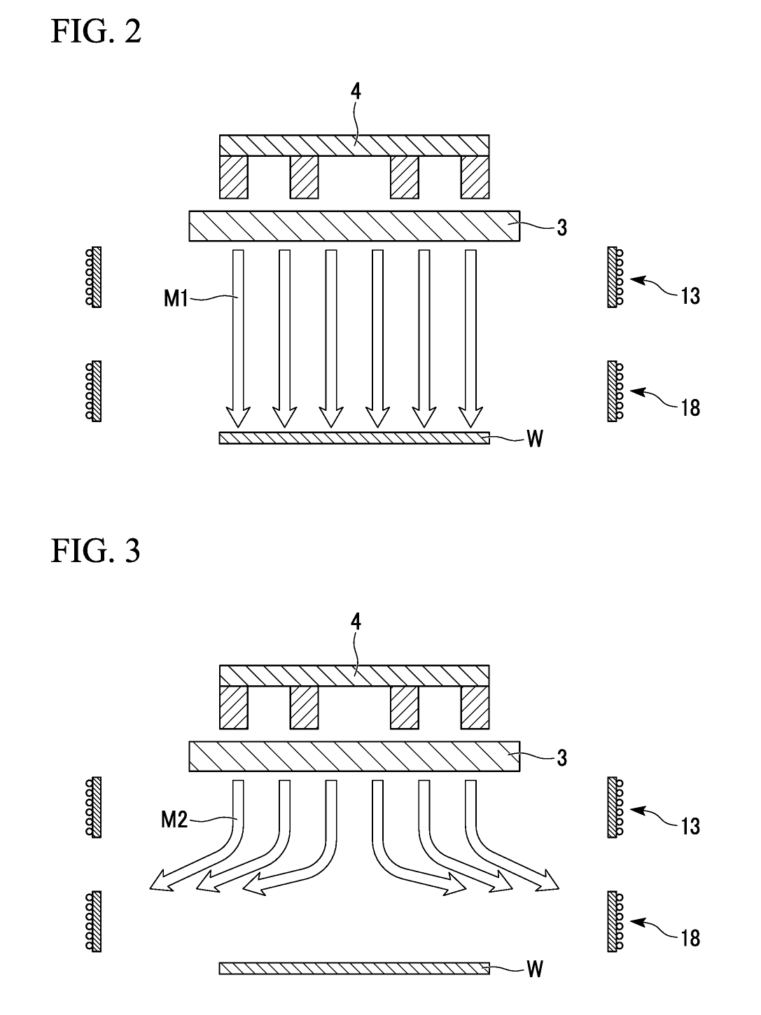

FIGS. 2 and 3 are views showing magnetic field lines M1 and M2 generated by the second magnetic field generation section 13 and the third magnetic field generation section 18.

In FIGS. 2 and 3, the magnetic field lines M1 and M2 is indicated by arrows, the arrows are illustrated for convenience and explanation, and the arrows do not limit the directions of magnetic fields.

That is, the magnetic field lines M1 and M2 includes both a direction from North polarity toward South polarity in the magnet and a direction from South polarity toward North polarity in the magnet.

FIG. 2 shows the magnetic field lines M1 in the case where negative electrical currents are applied to both coils 16 and 21.

By applying negative electrical currents to both coils, a magnetic field is generated so that the magnetic field lines M1 pass between the target 3 and the substrate W.

In contrast, FIG. 3 shows the magnetic field lines M2 in the case where negative electrical current is applied to the second coil 16 and positive electrical current is applied to the third coil 21.

Due to applying electrical current to each of the coils 16 and 21 so that the polarity of the electrical current applied to the second coil 16 is inverted to the polarity of the electrical current applied to the third coil 21, perpendicular magnetic field lines are generated near the target 3 and between the substrate W and the target 3.

However, the magnetic field lines do not travel toward the substrate W so as to maintain this direction of the magnetic field lines, and are deflected so as to be directed to the side walls of the vacuum chamber 2 from the substrate W.

Particularly, the directions of the magnetic field lines are converted into the direction, which is from the center of the vacuum chamber 2 to the side walls of the vacuum chamber 2, from the direction perpendicular to the substrate W.

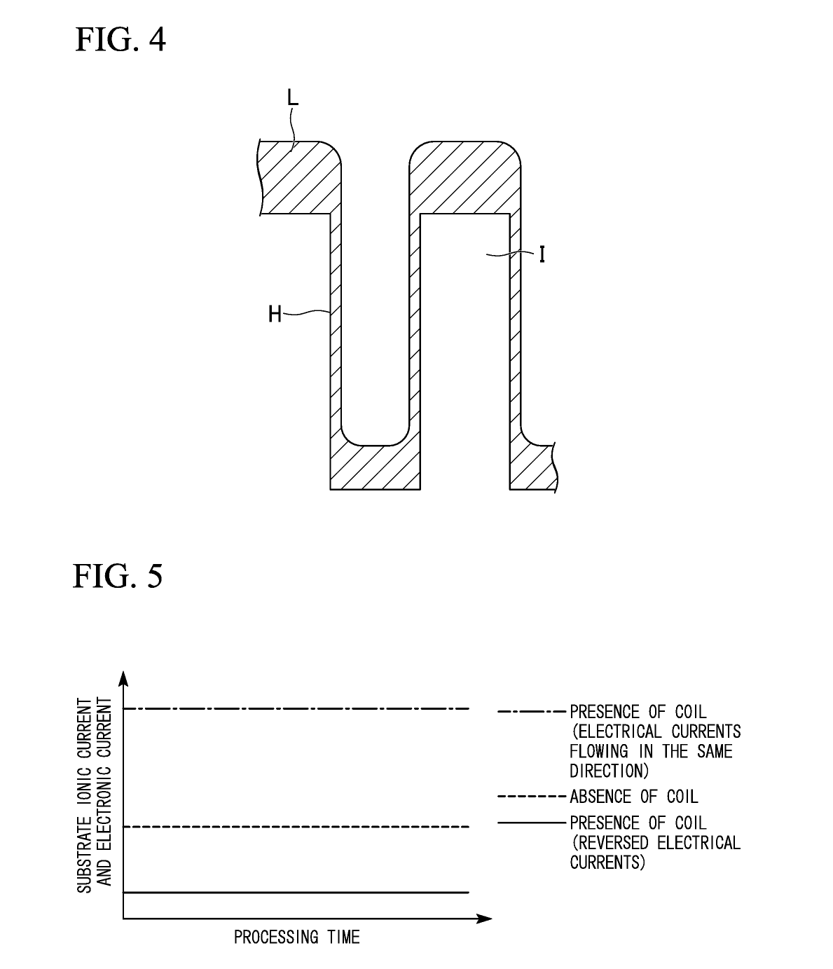

Next, a film forming method using the above-described film formation apparatus 1 and a coat formed by this method will be described with reference to FIG. 4.

Firstly, a Si wafer is prepared as a substrate W on which a coat is to be formed.

A silicon oxide film I is formed on the top face of this Si wafer, and microscopic holes H used for wiring are formed in this silicon oxide film I by patterning in advance using a known method.

Subsequently, the case of forming a Cu film L serving as a seed layer on the Si wafer by sputtering using the film formation apparatus 1 will be described.

At first, the pressure inside the vacuum chamber 2 is reduced by activating the vacuum pumping section 12 so as to reach a predetermined vacuum degree (for example, 10⁻⁵ Pa order).

Next, a substrate W (Si wafer) is mounted on the stage 10, simultaneously, electrical power is provided to the second coil 16 and the third coil 21 by activating the power supply devices 17 and 22, and the perpendicular magnetic field lines M are thereby generated between the target 3 and the substrate W.

Consequently, after the pressure inside the vacuum chamber 2 reaches a predetermined value, a predetermined negative electrical potential is applied (supplying electrical power) from the DC power source 9 to the target 3 while introducing argon gas or the like (sputter gas) into the inside of the vacuum chamber 2 at a predetermined flow rate.

For this reason, plasma atmosphere is generated in the vacuum chamber 2.

In this case, due to the magnetic field which is generated by the first magnetic field generation section 4, ionized electrons and secondary electrons generated by sputtering are captured in the space (anterior space) to which the sputtering face 3a is exposed, and plasma is generated in the inner space to which the sputtering face 3a is exposed.

Electrons and argon ions, which are broken free from the bound state which is due to the magnetic fields generated by the first magnetic field generation section 4, are deflected due to the magnetic field lines which are generated by the third magnetic field generation section 18 and directed to the side walls of the vacuum chamber 2 from the center of the vacuum chamber 2.

Because of this, it is possible to prevent argon ions and electrons from being incident to the substrate W in a state where the sputtered particles are incident to the substrate W.

On the other hand, argon ions in the plasma collide with the sputtering face 3a, accordingly, the sputtering face 3a is sputtered, Cu atoms or Cu ions are scattered from the sputtering face 3a toward the substrate W.

The directions in which the Cu atoms or Cu ions are scattered are changed due to the perpendicular magnetic field generated near the target 3, and Cu atoms or Cu ions are induced toward the substrate W.

At the time, particularly, by controlling and selecting the amount of the electrical currents and polarities which are adequately applied to the upper coil 16 and the lower coil 21, it is possible to prevent Cu having positive electrical charge similar to argon ions from being incident to the substrate due to the magnetic field lines which are directed from the center of the vacuum chamber 2 to the side walls of the vacuum chamber 2.

FIG. 5 shows a result of measuring ions and electronic current flowing into the substrate W.

Ions (electrons) electrical current was measured while attaching a predetermined probe to the place of the substrate W with which the sputtered particles collide.

This electrical current is represented as the substrate ions and electronic current in FIG. 5.

The higher the electrical current of the ions (electrons), the more ions and electrons reach the substrate W which mean that the substrate W is damaged or the substrate W is heated up.

In FIG. 5, the ionic currents were measures and compared with each other, which are the ionic current in the case where negative electrical current was applied to the second coil 16 and positive electrical current was applied to the third coil 21 (reversed electrical currents), the ionic current in the case where negative electrical currents were applied to both the second coil 16 and the third coil 21 (electrical currents flowing in the same direction), and the ionic current in the case where electrical currents were not applied to both the second coil 16 and the third coil 21 (no coil).

As a result, in the case of electrical currents flowing in the same direction, the ionic current remarkably increased as compared with the case of no coil.

The reason is that, it is thought that a large number of electrons reach the substrate W due to the perpendicular magnetic field M1 (refer to FIG. 2) as compared with the case of no coil, and the result thereby occurs as described above.

On the other hand, in the case of the electrical current being reversed, the amount of ionic current was reduced as compared with the case of the same direction of the electrical currents, furthermore, the ionic current decreased as compared with the case of no coil.

The reason is that, it is thought that, as a result of the polarity of the electrical current flowing into the second coil 16 being inverted with respect to the polarity of the electrical current flowing into the third coil 21 and the magnetic field lines due to the third coil 21 being inverted with respect to the magnetic field lines due to the second coil 16, the electrons reaching the substrate W was actively excluded, and the result thereby occurs as described above.

As a result described above, due to the polarity of the electrical current flowing into the third coil 21 being allowed to be inverted with respect to the polarity of the electrical current flowing into the second coil 16, the number of argon ions and electrons reaching the substrate W can be reduced, furthermore, it is possible to prevent damage to the substrate W and prevent an increase in temperature of the substrate W.

### INDUSTRIAL APPLICABILITY

The invention is widely applicable to a film formation apparatus used for forming a coat on a surface of a body to be processed, particularly, applicable to a film formation apparatus employing a DC magnetron method using a sputtering method which is one of several thin film forming methods.

What is claimed is:

1. A film formation apparatus comprising:
a chamber having a side wall and an inner space in which both a body to be processed on which a film is to be formed and a target having a sputtering face are disposed so that the body to be processed is opposed to the target;
a pumping section reducing a pressure inside the chamber;
a first magnetic field generation section generating a magnetic field in the inner space to which the sputtering face is exposed;
a direct-current power source applying a negative direct electric current voltage to the target;
a gas introduction section introducing a sputter gas into the chamber;
a second magnetic field generation section disposed at a position close to the target, the second magnetic field generation section generating a magnetic field so as to allow perpendicular magnetic lines of force thereof to pass through a position adjacent to the target; and
a third magnetic field generation section disposed at a position close to the body to be processed, the third magnetic field generation section generating a magnetic field so as to induce the magnetic lines of force to the side wall of the chamber.

2. The film formation apparatus according to claim 1, wherein
the second magnetic field generation section and the third magnetic field generation section are distantly-disposed from each other at a predetermined distance around the chamber, and are constituted of coils which are provided with a power supply device, and
electrical currents are applied to the second magnetic field generation section and the third magnetic field generation section so that a polarity of the electrical current applied to the second magnetic field generation section is opposite to a polarity of the electrical current applied to the third magnetic field generation section.

3. The film formation apparatus according to claim 2, wherein
magnetic field lines which are generated by the second magnetic field generation section and the third magnetic field generation section are induced to the chamber.
